(19) United States
(12) Patent Application Publication
(10) Pub. No.: US 2022/0310317 A1
(43) Pub. Date: Sep. 29, 2022

(54) ELECTRONIC COMPONENT MODULE

(71) Applicant: Murata Manufacturing Co., Ltd., Nagaokakyo-shi (JP)

(72) Inventors: Minoru KOMIYAMA, Nagaokakyo-shi (JP); Motohiko KUSUNOKI, Nagaokakyo-shi (JP); Mitsuo ISHIDO, Nagaokakyo-shi (JP); Toru KOMATSU, Nagaokakyo-shi (JP)

(21) Appl. No.: 17/806,748

(22) Filed: Jun. 14, 2022

Related U.S. Application Data
(63) Continuation of application No. PCT/JP2020/043595, filed on Nov. 24, 2020.

(30) Foreign Application Priority Data
Dec. 20, 2019 (JP) 2019-229952

(51) Int. Cl. H01F 27/29; H05K 3/46; H01F 27/28

(52) U.S. Cl. CPC H01F 27/292; H05K 3/4685; H01F 27/2804

(57) ABSTRACT

An electronic component module includes a substrate with a first main surface and a second main surface. Mount electronic components and a second conductive member are mounted on the second main surface, and the second conductive member is disposed between the mount electronic component and the mount electronic component. The second conductive member is connected to a shield film disposed near the second main surface through a depression. Mount electronic components and a first conductive member are mounted on the first main surface, and the first conductive member is disposed between the mount electronic component and the mount electronic component. The first conductive member is connected to a shield film disposed near the first main surface through a depression.

### CROSS REFERENCE TO RELATED APPLICATION

This is a continuation of International Application No. PCT/JP2020/043595 filed on Nov. 24, 2020 which claims priority from Japanese Patent Application No. 2019-229952 filed on Dec. 20, 2019. The contents of these applications are incorporated herein by reference in their entireties.

### BACKGROUND OF THE DISCLOSURE

### Field of the Disclosure

The present disclosure relates to an electronic component module in which a plurality of electronic components are mounted on a substrate.

### Description of the Related Art

Patent Literature 1 discloses a high frequency module in which a plurality of components are mounted on a bottom surface of a multilayer wiring substrate. A shield wall is disposed between the components on the bottom surface of the multilayer wiring substrate.

The shield wall is provided by forming a groove in a sealing resin layer formed on the bottom surface of the multilayer wiring substrate, and then filling the groove with conductive paste or using a sputtering method.

Patent Literature 1: International Publication No. 2018/101384

### BRIEF SUMMARY OF THE DISCLOSURE

However, in the conventional high frequency module, a process of forming a shield wall by laser machining or the like, the multilayer wiring substrate may be damaged. In addition, a process of forming other components must be provided separately.

Therefore, exemplary embodiments of the present disclosure are directed to provide a double-sided mount electronic component module capable of being obtained in a simple process and having high isolation between components.

An electronic component module according to the present disclosure includes a substrate including a first main surface and a second main surface, the first main surface being a mounting side, a first electronic component and a second electronic component each mounted on the first main surface, a first conductive member mounted on the first main surface and disposed between the first electronic component and the second electronic component, a first insulating resin covering a side of the first main surface, and a first shield film provided on one surface of the first insulating resin, the one surface being opposite to a surface of the first insulating resin facing the first main surface of the substrate. The first insulating resin includes a first depression exposing the first conductive member from the first insulating resin, at a portion overlapping with the first conductive member. The first shield film is provided in the first depression of the first insulating resin and is connected to the first conductive member.

With this configuration, isolation between the first electronic component and the second electronic component is obtained by the first conductive member mounted similarly to the substrate on which the first electronic component and the second electronic component are mounted. Then, the first conductive member, simultaneously with the first electronic component and the second electronic component, is able to be mounted on the substrate. Furthermore, the first shield film is provided in the depression provided in an insulating resin near the first main surface, so that the first conductive member and the first shield film for grounding are connected to each other. As a result, the configuration capable of obtaining high isolation is achieved by a simple process.

According to exemplary embodiments of the present disclosure, a double-sided mount electronic component module with high isolation between components is able to be provided by a simple process.

### BRIEF DESCRIPTION OF THE SEVERAL VIEWS OF THE DRAWINGS

FIG. 1A is a side cross-sectional view showing a configuration of an electronic component module according to a first exemplary embodiment of the present disclosure, and FIG. 1B is a rear view of the electronic component module according to the first exemplary embodiment.

FIG. 2 is a flow chart showing a method of manufacturing the electronic component module according to the first exemplary embodiment.

FIG. 3A, FIG. 3B, and FIG. 3C are side cross-sectional views showing a configuration in each process step of a manufacturing process.

FIG. 4A, FIG. 4B, and FIG. 4C are side cross-sectional views showing a configuration in each process step of a manufacturing process.

FIG. 5A is a side cross-sectional view showing a configuration of an electronic component module according to a second exemplary embodiment of the present disclosure, and FIG. 5B is a rear view of the electronic component module according to the second exemplary embodiment.

FIG. 6A is a side cross-sectional view showing a configuration of an electronic component module according to a third exemplary embodiment of the present disclosure, and FIG. 6B is a rear view of the electronic component module according to the third exemplary embodiment.

FIG. 7 is a rear view of an electronic component module according to a fourth exemplary embodiment of the present disclosure.

FIG. 8 is a rear view of an electronic component module according to a fifth exemplary embodiment of the present disclosure.

### DETAILED DESCRIPTION OF THE DISCLOSURE

### First Exemplary Embodiment

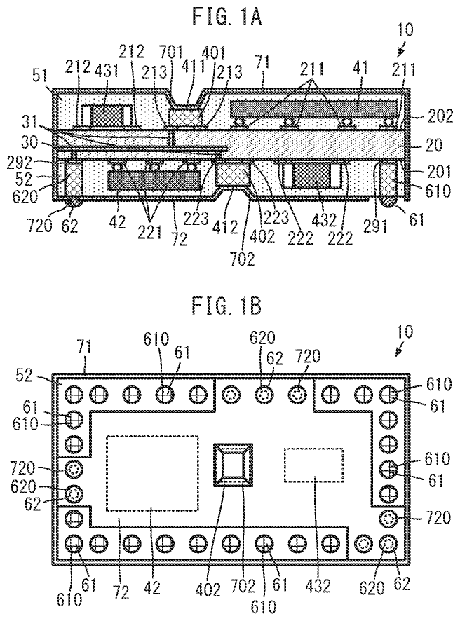

An electronic component module according to a first exemplary embodiment of the present disclosure will be described with reference to drawings. FIG. 1A is a side cross-sectional view showing a configuration of the electronic component module according to the first exemplary embodiment of the present disclosure, and FIG. 1B is a rear view of the electronic component module according to the first exemplary embodiment. It is to be noted that, in FIG. 1B, in order to easily distinguish between an external connection terminal conductor and a ground terminal conductor, hatching is added to a solder bump of the external connection terminal conductor.

As shown in FIG. 1A and FIG. 1B, an electronic component module 10 includes a substrate 20, a mount electronic component 41, a mount electronic component 42, a mount electronic component 431, a mount electronic component 432, a second conductive member 401, a first conductive member 402, an insulating resin 51, an insulating resin 52, a plurality of external connection terminal conductors 610, a plurality of ground terminal conductors 620, a plurality of solder bumps 61, a plurality of solder bumps 62, a shield film 71, and a shield film 72.

The substrate 20 has an insulating main body and includes a conductor pattern to implement the electronic component module 10. The substrate 20, while being configured such that a plurality of insulator layers including a predetermined conductor pattern are stacked, for example, is not limited to such a configuration. For example, the substrate 20 may be a single layer.

The conductor pattern includes a ground conductor pattern 30 and a plurality of ground interlayer connection conductors 31. The ground conductor pattern 30 is shaped to extend in a direction perpendicular to a thickness direction of the substrate 20. One end of the ground conductor pattern 30 is exposed to a side surface of the substrate 20. The plurality of ground interlayer connection conductors 31 are shaped to extend in parallel with the thickness direction of the substrate 20. The plurality of ground interlayer connection conductors 31 are connected to the ground conductor pattern 30. It is to be noted that illustration of other conductor patterns provided inside the substrate 20 is omitted.

The substrate 20 is, for example, a rectangular flat plate, and has a first main surface 201 and a second main surface 202 facing each other. The first main surface 201 corresponds to a rear surface of the substrate, for example, and the second main surface 202 corresponds to a front surface of the substrate, for example. The substrate 20 is a ceramic multilayer substrate. Alternatively, the substrate 20 may be a resin multilayer substrate.

A plurality of land conductors 211, a plurality of land conductors 212, and a plurality of land conductors 213 are provided on the second main surface 202 of the substrate 20. The plurality of land conductors 213 are disposed between a region in which the plurality of land conductors 211 are provided and a region in which the plurality of land conductors 212 are provided. At least one of the plurality of land conductors 213 is connected to the ground interlayer connection conductor 31.

A plurality of land conductors 221, a plurality of land conductors 222, a plurality of land conductors 223, a plurality of external connection land conductors 291, and a plurality of ground land conductors 292 are provided on the first main surface 201 of the substrate 20. The plurality of land conductors 223 are disposed between a region in which the plurality of land conductors 221 are provided and a region in which the plurality of land conductors 222 are provided. At least one of the plurality of land conductors 223 is connected to the ground interlayer connection conductor 31.

The plurality of external connection land conductors 291 and the plurality of ground land conductors 292 are arranged along an outer peripheral end in the vicinity of the outer peripheral end on the first main surface 201 of the substrate 20. It is to be noted that the plurality of external connection land conductors 291 and the plurality of ground land conductors 292 need not necessarily be arranged along the outer peripheral end of the substrate.

The mount electronic component 41 and the mount electronic component 42 are electronic components using a semiconductor or a piezoelectric body, for example. The mount electronic component 41 is an electronic component that easily generates noise such as high harmonic, for example. For example, the mount electronic component 42 corresponds to a “first electronic component” of the present disclosure, and the mount electronic component 41 corresponds to a “third electronic component” of the present disclosure.

The mount electronic component 431 and the mount electronic component 432 are, for example, chip capacitor elements, chip inductor elements, chip resistance elements, or the like. For example, the mount electronic component 432 corresponds to a “second electronic component” of the present disclosure, and the mount electronic component 431 corresponds to a “fourth electronic component” of the present disclosure. It is to be noted that the mount electronic component 431 and the mount electronic component 432 may be electronic components that generate noise.

The second conductive member 401 and the first conductive member 402 is made of chip-shaped (rectangular parallelepiped shaped, for example) metal. The metal is copper (Cu), for example. It is to be noted that the second conductive member 401 and the first conductive member 402 may be mainly metal and may include an insulating resist film at a location other than a terminal portion, as an exterior.

The mount electronic component 41 is bonded (mounted) to the land conductor 211 by using solder or the like. The mount electronic component 431 is bonded (mounted) to the land conductor 212 by using solder or the like. The second conductive member 401 is bonded (mounted) to the land conductor 213 by using solder or the like. As a result, the second conductive member 401 is disposed between the mount electronic component 41 and the mount electronic component 431.

The second conductive member 401 made of metal as described above receives noises such as high harmonic. Therefore, such a configuration is able to reduce electromagnetic interference between the mount electronic component 41 and the mount electronic component 431 and ensure isolation between the mount electronic component 41 and the mount electronic component 431.

The mount electronic component 42 is bonded (mounted) to the land conductor 221 by using solder or the like. The mount electronic component 432 is bonded (mounted) to the land conductor 222 by using solder or the like. The first conductive member 402 is bonded (mounted) to the land conductor 223 by using solder or the like. As a result, the first conductive member 402 is disposed between the mount electronic component 42 and the mount electronic component 432.

The first conductive member 402 made of metal as described above receives noises such as high harmonic. Therefore, such a configuration is able to reduce electromagnetic interference between the mount electronic component 42 and the mount electronic component 432 and ensure isolation between the mount electronic component 42 and the mount electronic component 432.

The plurality of external connection terminal conductors 610 and the plurality of ground terminal conductors 620 are columnar conductors made of metal such as copper. The plurality of external connection terminal conductors 610 are bonded (mounted) to the plurality of external connection land conductors 291 by using solder or the like. The plurality of ground terminal conductors 620 are bonded (mounted) to the plurality of ground land conductors 292 by using solder or the like. It is to be noted that the plurality of external connection terminal conductors 610 and the plurality of ground terminal conductors 620 may be projecting electrodes formed by plating or the like, metal pins, via conductors, or the like.

The plurality of solder bumps 61 are provided at a tip (an end opposite to an end to be connected to the plurality of external connection land conductors 291) of the plurality of external connection terminal conductors 610. The plurality of solder bumps 62 are provided at a tip (one end opposite to the other end to be connected to the plurality of ground land conductors 292) of the plurality of ground terminal conductors 620.

The electronic component module 10 is mounted to a different circuit board by using the solder bumps 61. In other words, in the electronic component module 10, the first main surface 201 of the substrate 20 is a mounting side to the different circuit board. In addition, the electronic component module 10 is connected to an external ground by using the solder bumps 62. In other words, the electronic component module 10 is grounded through the solder bumps 62.

The insulating resin 51 covers a side of the second main surface 202 of the substrate 20. The insulating resin 51 corresponds to the “second insulating resin” of the present disclosure. The insulating resin 51 covers an entire surface of the mount electronic component 41 and the mount electronic component 431. It is to be noted that the insulating resin 51 may be shaped so as to expose the top surface of the mount electronic component 41.

In addition, the insulating resin 51 covers the mounting surface and side surface of the second conductive member 401. In other words, the insulating resin 51 is provided so as to expose the top surface 411 (a surface opposite to a mounting surface) of the second conductive member 401 from the insulating resin 51. More specifically, the insulating resin 51 includes a depression in a region that overlaps with the second conductive member 401. The bottom surface of this depression is provided by the top surface 411 (the surface opposite to the mounting surface) of the second conductive member 401.

The insulating resin 52 covers a side of the first main surface 201 of the substrate 20. The insulating resin 52 corresponds to the “first insulating resin” of the present disclosure. The insulating resin 52 covers an entire surface of the mount electronic component 42 and the mount electronic component 432. It is to be noted that the insulating resin 52 may be shaped so as to expose the top surface of the mount electronic component 42.

In addition, the insulating resin 52 covers the mounting surface and side surface of the first conductive member 402. In other words, the insulating resin 52 is provided so as to expose the top surface 412 (a surface opposite to a mounting surface) of the first conductive member 402 from the insulating resin 52. More specifically, the insulating resin 52 includes a depression in a region that overlaps with the first conductive member 402. The bottom surface of this depression is provided by the top surface 412 (the surface opposite to the mounting surface) of the first conductive member 402.

The insulating resin 51 and the insulating resin 52 are able to protect the mount electronic component 41, the mount electronic component 42, the mount electronic component 431, the mount electronic component 432, and various conductor patterns provided on the first main surface 201 and the second main surface 202 of the substrate 20, from the external environment.

The shield film 71 and the shield film 72 are conductive films. The shield film 71 corresponds to a “second shield film” of the present disclosure, and the shield film 72 corresponds to a “first shield film” of the present disclosure.

The shield film 71 covers an entire outer surface of the insulating resin 51, an entire side surface of the substrate 20, and an entire side surface of the insulating resin 52. In such a case, the shield film 71 is connected to the ground conductor pattern 30 exposed to the side surface of the substrate 20.

In addition, the shield film 71 covers the top surface 411 of the second conductive member 401. Accordingly, the shield film 71 and the second conductive member 401 are connected and then electrically connected to each other.

The shield film 72 partially covers a surface (hereafter referred to as a mounting surface) of the insulating resin 52, the surface being opposite to a surface in contact with the first main surface 201 of the substrate 20. More specifically, as shown in FIG. 1B, the shield film 72 is provided so as to exclude an exposure region in the mounting surface (the rear surface) to which the plurality of external connection terminal conductors 610 are exposed. The plurality of external connection terminal conductors 610 and the shield film 72 are spaced apart and are not electrically connected to each other. Furthermore, the shield film 72 is provided so as to include the depression of the insulating resin 52. In other words, the shield film 72 includes a depression 702. Moreover, the shield film 72 is provided so as to include positions that overlap with the mount electronic component 42 and the mount electronic component 432 and also include an exposure region to which the plurality of ground terminal conductors 620 are exposed. In other words, the shield film 72 overlaps with at least either one of the mount electronic component 42 and the mount electronic component 432 in a plan view.

In addition, the shield film 72 is electrically connected to the shield film 71 on the side surface of the substrate 20. Specifically, a portion including the exposure region of the plurality of ground terminal conductors 620 in the shield film 72 is shaped to extend to a side end of the mounting surface. A tip portion of such an extended shape is connected to the shield film 71 provided on the side surface of the insulating resin 52.

In such a manner, the shield film 71 and the shield film are able to significantly reduce or prevent unnecessary coupling and interference between the mount electronic component 41, the mount electronic component 42, the mount electronic component 431, the mount electronic component 432, and an electrical configuration provided in the substrate 20 and the external environment.

In addition, the shield film 72 includes an opening in a center of the exposure region of the plurality of ground terminal conductors 620. This opening is a hole passing through the shield film 72 in the thickness direction, and thus the plurality of ground terminal conductors 620 are exposed to outside near the mounting surface when no solder bumps 62 are provided. The solder bumps 62 are provided so as to fill this opening. As a result, the shield film 72 and the ground terminal conductors 620 are more securely and physically bonded and electrically connected to each other.

With such a structure, the shield film 72 is more securely connected to an external ground potential through the ground terminal conductors 620. The shield film 72 is electrically connected to the shield film 71, which enables the electronic component module 10 to more effectively reduce the unnecessary coupling and interference with the external environment.

In addition, with an above configuration, the first conductive member 402 is electrically connected to the shield film 72 through the depression 702. Similarly, the second conductive member 401 is electrically connected to the shield film 71 through a depression 701. Accordingly, the first conductive member 402 and the second conductive member 401 are connected to a ground potential. As a result, the effect of reducing electromagnetic interference by the first conductive member 402 is further increased. Similarly, the effect of reducing electromagnetic interference by the second conductive member 401 is further increased.

Moreover, the first conductive member 402 and the shield film 72 are in surface contact with the bottom portion of the depression 702, so that the reliability of connection between the first conductive member 402 and the shield film 72 is improved, and the connection resistance is also reduced. Similarly, the second conductive member 401 and the shield film are in surface contact with the bottom portion of the depression 701, so that the reliability of connection between the second conductive member 401 and the shield film 71 is improved, and the connection resistance is also reduced.

In particular, the first conductive member 402 is connected to the solder bumps 62 of the ground terminal conductors 620 not only through the ground conductor pattern 30 and the ground interlayer connection conductor 31 but also through the shield film 72. As a result, the first conductive member 402 has a short distance to the ground potential, and is able to obtain more stable grounding effects. Therefore, the effect of reducing the electromagnetic interference by the first conductive member 402 is further increased and stabilized.

In addition, the first conductive member 402 is electrically connected to the shield film 72, which is able to reduce the electromagnetic interference through a side of the top surface 412 of the first conductive member 402. Similarly, the second conductive member 401 is electrically connected to the shield film 71, which is able to reduce the electromagnetic interference through a side of the top surface 411 of the second conductive member 401.

In addition, in this configuration, the first conductive member 402 is able to be mounted on the substrate 20 by the same mounting process as with the mount electronic component 42 and the mount electronic component 432. As a result, the structure that reduces the electromagnetic interference of the mount electronic component 42 and the mount electronic component 432 is able to be achieved without adding a new different process step. Then, the electrical connection between the first conductive member 402 and the shield film 72 is also able to be achieved only by the shield film 72 provided in the depression of the insulating resin 52. Therefore, the electronic component module 10 is able to be obtained by a simpler process.

Similarly, in this configuration, the second conductive member 401 is able to be mounted on the substrate 20 by the same mounting process as with the mount electronic component 41 and the mount electronic component 431. As a result, the structure that reduces the electromagnetic interference of the mount electronic component 41 and the mount electronic component 431 is able to be achieved without adding a new different process step. Then, the electrical connection between the second conductive member 401 and the shield film 71 is also able to be achieved only by the shield film 71 provided in the depression of the insulating resin 51. Therefore, the electronic component module 10 is able to be obtained by a simpler process.

In addition, in this configuration, the second conductive member 401 is able to be connected to the first conductive member 402 through the ground conductor pattern 30 and the ground interlayer connection conductor 31 in the substrate 20. As a result, a connection distance between the second conductive member 401 and the first conductive member 402 is able to be reduced, which further stabilizes the ground potential of the second conductive member 401.

Moreover, in this configuration, the ground conductor pattern 30 in the substrate 20 is connected to the shield film 71 on the side surface of the substrate 20. As a result, a connection distance between the second conductive member 401 and the first conductive member 402, and the shield film 71 on the side surface of the substrate 20 is able to be reduced.

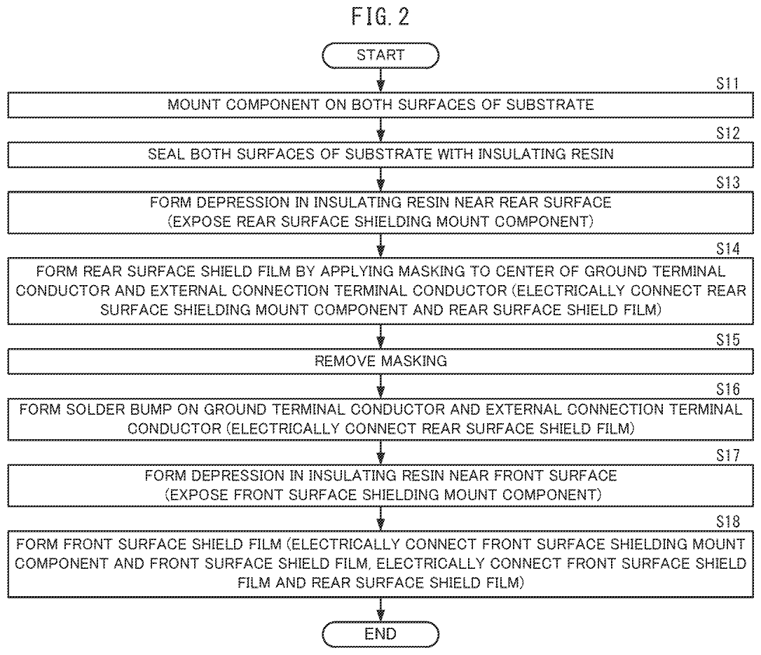

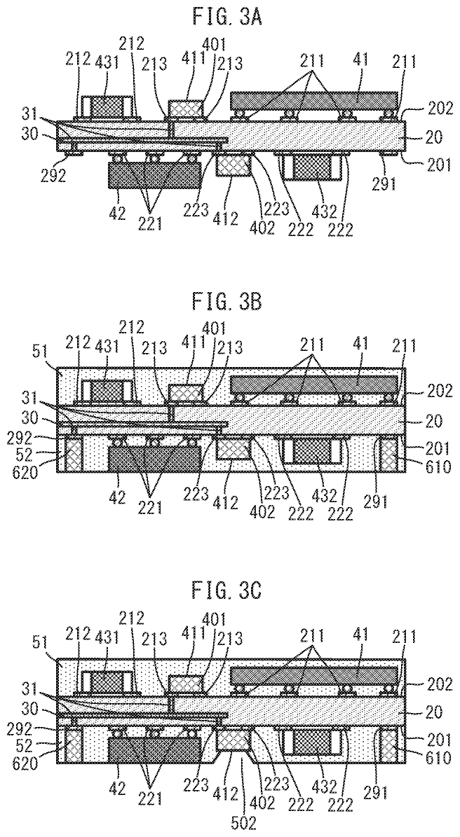

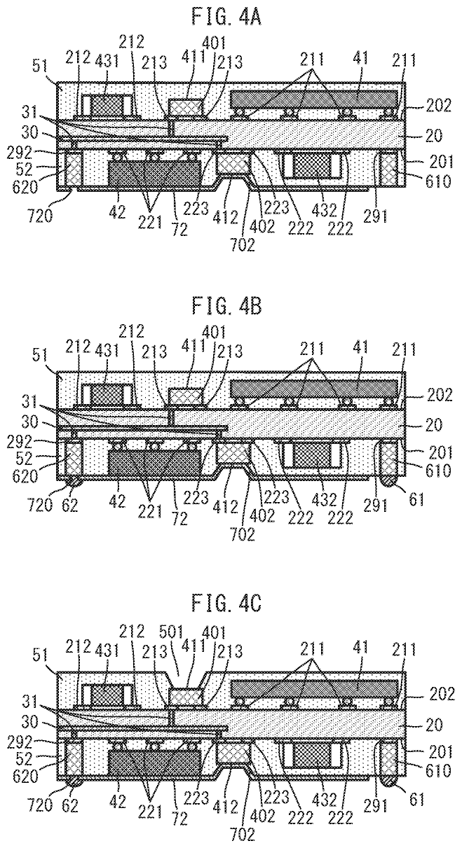

The electronic component module 10 of such a configuration is able to be provided by the following manufacturing method. FIG. 2 is a flow chart showing a method of manufacturing the electronic component module according to the first exemplary embodiment. FIG. 3A, FIG. 3B, and FIG. 3C, FIG. 4A, FIG. 4B, and FIG. 4C are side cross-sectional views showing a configuration in each process step of a manufacturing process.

First, as shown in FIG. 3A, components are mounted on both surfaces of the substrate 20 (S11). More specifically, the mount electronic component 41, the mount electronic component 431, and the second conductive member 401 are mounted on the second main surface 202 of the substrate 20. In addition, the mount electronic component 42, the mount electronic component 432, the first conductive member 402, the external connection terminal conductor 610, and the ground terminal conductor 620 are mounted on the first main surface 201 of the substrate 20.

Next, as shown in FIG. 3B, both surfaces of the substrate 20 are sealed with an insulating resin (S12). More specifically, the side of the second main surface 202 of the substrate 20 is sealed with the insulating resin 51. At this time, the insulating resin 51 is provided so as to cover the entire mounting electronic component 41, the entire mount electronic component 431, and the entire second conductive member 401. In addition, the side of the first main surface 201 of the substrate 20 is sealed with the insulating resin 52. At this time, the insulating resin 52 is provided so as to cover the entire mounting electronic component 42, the entire mounting electronic component 432, the entire first conductive member 402, the entire external connection terminal conductor 610, and the entire ground terminal conductor 620.

Subsequently, as shown in FIG. 3C, the insulating resin on the rear surface of the substrate 20 is ground to a predetermined thickness to form the depression 502 (S13). More specifically, the insulating resin 52 is ground so as to expose the tip of the external connection terminal conductor 610 and ground terminal conductor 620, and the depression 502 is formed in the region that overlaps with the first conductive member 402 so as to expose the top surface 412 of the first conductive member 402.

Next, as shown in FIG. 4A, the shield film 72 is formed. More specifically, masking is applied to the center of the ground terminal conductor 620, and the external connection terminal conductor 610 to form the shield film 72 by sputtering or the like (S14). At this time, the shield film 72 is formed so as to cover a wall surface of the depression 502. As a result, the first conductive member 402 and the shield film 72 are connected and then electrically connected to each other. In addition, an opening 720 is formed at a portion of the shield film 72 that overlaps with the center of the ground terminal conductor 620. After the shield film 72 is provided, the masking is removed (S15).

Subsequently, as shown in FIG. 4B, a solder bump 62 is formed in the center (the opening 720 of the shield film 72) at the tip of the ground terminal conductor 620, and a solder bump is formed at the tip of the external connection terminal conductor 610 (S16). The solder bump 62 improves the reliability of connection between the ground terminal conductor 620 and the shield film 72.

Subsequently, as shown in FIG. 4C, the insulating resin on the front surface of the substrate 20 is ground to a predetermined thickness to form the depression 501 (S17). More specifically, the insulating resin 51 is ground to a predetermined thickness to form the depression 501 so that the top surface 411 of the second conductive member 401 may be exposed in the region that overlaps with the second conductive member 401.

Next, the shield film 71 that also has a function as a front side shield film is formed (S18). More specifically, the shield film 71 is formed by sputtering or the like so as to cover the entire outer surface of the insulating resin 51, the entire side surface of the substrate 20, and the entire side surface of the insulating resin 52. At this time, the shield film 71 is formed so as to cover a wall surface of the depression 501. As a result, the second conductive member 401 and the shield film 71 are connected and then electrically connected to each other.

The electronic component module 10 is able to be manufactured by using the above manufacturing process steps. By using such a manufacturing method, it is possible to use the same process to mount a shield mount component and a mount electronic component and perform the same process for grinding an insulating resin and forming a depression. Therefore, as described above, the electronic component module 10 capable of reducing the electromagnetic interference between mount electronic components is able to be obtained by a simple process. It is to be noted that the manufacturing process may further include a different process step such as a step of making an individual piece or may change the order of process steps.

### Second Exemplary Embodiment

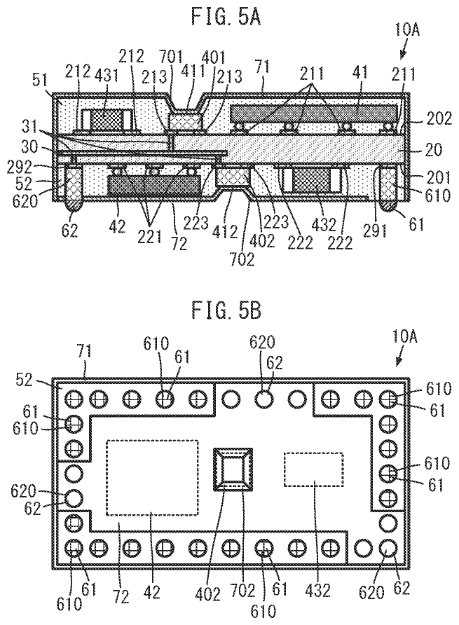

An electronic component module according to a second exemplary embodiment of the present disclosure will be described with reference to the drawings. FIG. 5A is a side cross-sectional view showing a configuration of the electronic component module according to the second exemplary embodiment of the present disclosure, and FIG. 5B is a rear view of the electronic component module according to the second exemplary embodiment. It is to be noted that, in FIG. 5B, in order to easily distinguish between an external connection terminal conductor and a ground terminal conductor, hatching is added to a solder bump of the external connection terminal conductor.

As shown in FIG. 5A and FIG. 5B, the electronic component module 10A according to the second exemplary embodiment is different in disposition of the shield film 72 from the electronic component module 10 according to the first exemplary embodiment. Other configurations of the electronic component module 10A are the same as or similar to the configurations of the electronic component module 10, and a description of the same or similar configuration will be omitted.

The shield film 72 is disposed on a surface (a mounting surface) of the insulating resin 52, opposite to a surface in contact with the substrate 20. At this time, the outer surface of the shield film 72 is flush with the mounting surface of the insulating resin 52. In other words, the shield film 72 is disposed so as to be filled in the depression provided in the surface opposite to the insulating resin 52.

Even with such a configuration, the electronic component module 10A is able to obtain the same effects and advantages as the effects and advantages of the electronic component module 10. Furthermore, the electronic component module 10A is able to be smaller in thickness of a portion other than the solder bump smaller than the electronic component module 10.

### Third Exemplary Embodiment

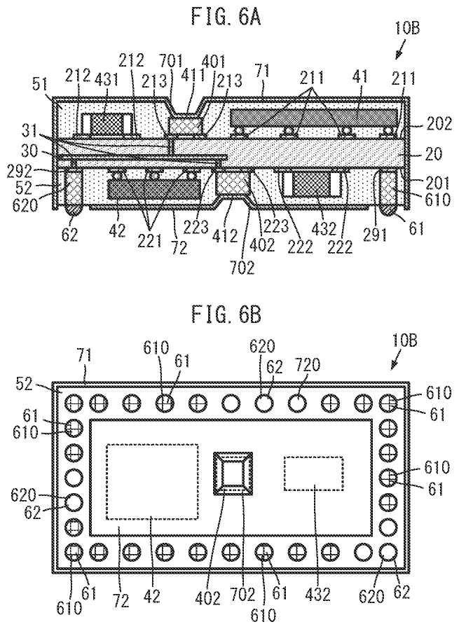

An electronic component module according to a third exemplary embodiment of the present disclosure will be described with reference to the drawings. FIG. 6A is a side cross-sectional view showing a configuration of the electronic component module according to the third exemplary embodiment of the present disclosure, and FIG. 6B is a rear view of the electronic component module according to the third exemplary embodiment. It is to be noted that, in FIG. 6B, in order to easily distinguish between an external connection terminal conductor and a ground terminal conductor, hatching is added to a solder bump of the external connection terminal conductor.

As shown in FIG. 6A and FIG. 6B, an electronic component module 10B according to the third exemplary embodiment is different from the electronic component module 10 according to the first exemplary embodiment in that the shield film 72 and the shield film 71 are not connected on the outer surface of the insulating resin 52. Other configurations of the electronic component module 10B are the same as or similar to the configurations of the electronic component module 10, and a description of the same or similar configuration will be omitted.

The shield film 72, when the insulating resin 52 is viewed in a plan view (from the rear surface), is provided in a region more inside than the region in which the plurality of external connection terminal conductors 610 and the plurality of ground terminal conductors 620 are provided. The shield film is not connected to the plurality of ground terminal conductors 620.

Even with such a configuration, the electronic component module 10B is able to obtain the same effects and advantages as the effects and advantages of the electronic component module 10. In addition, this configuration is able to separate influence on the shield film 71 from the outside from influence on the shield film 72 from the outside.

### Fourth Exemplary Embodiment

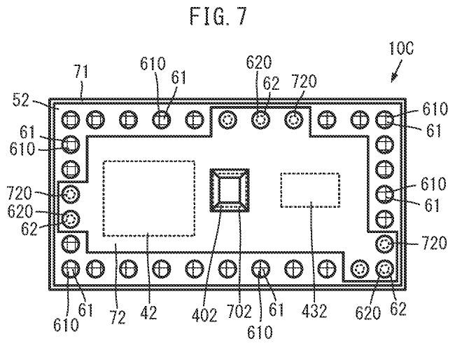

An electronic component module according to a fourth exemplary embodiment of the present disclosure will be described with reference to the drawings. FIG. 7 is a rear view of an electronic component module according to a fourth exemplary embodiment. It is to be noted that, in FIG. 7, in order to easily distinguish between an external connection terminal conductor and a ground terminal conductor, hatching is added to a solder bump of the external connection terminal conductor.

As shown in FIG. 7, an electronic component module 10C according to the fourth exemplary embodiment is different from the electronic component module 10 according to the first exemplary embodiment in that the shield film 72 and the shield film 71 are not connected on the outer surface of the insulating resin 52. Other configurations of the electronic component module 10C are the same as or similar to the configurations of the electronic component module 10, and a description of the same or similar configuration will be omitted.

The shield film 72 and the shield film 71 are separated from each other. The shield film 72 is connected to the plurality of ground terminal conductors 620.

Even with such a configuration, the electronic component module 10C is able to obtain the same effects and advantages as the effects and advantages of the electronic component module 10. In addition, this configuration, while ensuring the electrical connection between the ground terminal conductors 620 and the shield film 72, is able to separate influence on the shield film 71 from the outside from influence on the shield film 72 from the outside.

### Fifth Exemplary Embodiment

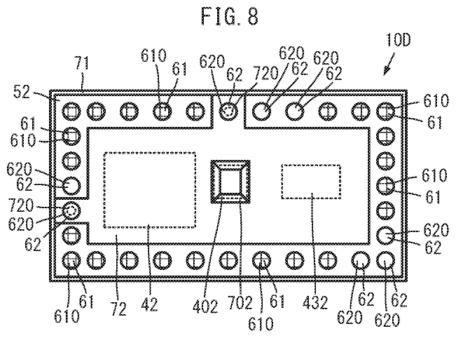

An electronic component module according to a fifth exemplary embodiment of the present disclosure will be described with reference to the drawings. FIG. 8 is a rear view of the electronic component module according to the fifth exemplary embodiment. It is to be noted that, in FIG. 8, in order to easily distinguish between an external connection terminal conductor and a ground terminal conductor, hatching is added to a solder bump of the external connection terminal conductor.

As shown in FIG. 8, the electronic component module 10D according to the fifth exemplary embodiment is different in configuration in which the plurality of ground terminal conductors 620 are connected to the shield film 72 from the electronic component module 10 according to the first exemplary embodiment. Other configurations of the electronic component module 10D are the same as or similar to the configurations of the electronic component module 10, and a description of the same or similar configuration will be omitted.

Some of the plurality of ground terminal conductors 620 are electrically connected to the shield film 72, and others are not electrically connected to the shield film 72.

Even with such a configuration, the electronic component module 10C is able to obtain the same effects and advantages as the effects and advantages of the electronic component module 10. In addition, this configuration is able to increase possible patterns of connection between the ground terminal conductors 620 and the shield film 72. In other words, design flexibility in configuration of connection between the ground terminal conductors 620 and the shield film 72 is increased.

It is to be noted that, in each of the above exemplary embodiments, the number of sets of the mount electronic components that reduce the electromagnetic interference is one. However, the number of sets is not limited to one, and, for each set that reduces the electromagnetic interference, a conductive member may be mounted and connected to a shield film with a depression.
10, 10A, 10B, 10C, 10D: electronic component module
20: substrate
30: ground conductor pattern
31: ground interlayer connection conductor
41, 42, 431, 432: mount electronic component
51, 52: insulating resin
61, 62: solder bump
71, 72: shield film
201: first main surface
202: second main surface
211, 212, 213, 221, 222, 223: land conductor
291: external connection land conductor
292: ground land conductor
401: second conductive member
402: first conductive member
411, 412: top surface
501, 502: depression
610: external connection terminal conductor
620: ground terminal conductor
701, 702: depression
720: opening

1. An electronic component module comprising:
a substrate including a first main surface and a second main surface, the first main surface being a mounting side;
a first electronic component and a second electronic component each mounted on the first main surface;
a first conductive member mounted on the first main surface and disposed between the first electronic component and the second electronic component;
a first insulating resin covering a side of the first main surface; and
a first shield film provided on one surface of the first insulating resin, the one surface being opposite to a surface of the first insulating resin facing the first main surface of the substrate, wherein:
the first insulating resin includes a first depression exposing the first conductive member from the first insulating resin at a portion overlapping with the first conductive member;
the first shield film is provided in the first depression of the first insulating resin and is connected to the first conductive member;
the substrate includes a ground terminal conductor on the first main surface;
the first shield film includes an opening overlapping with a portion of the ground terminal conductor; and
the first shield film and the ground terminal conductor are connected by a solder bump including a portion to be filled in the opening.

2. The electronic component module according to claim 1, wherein the first shield film overlaps with at least one of the first electronic component and the second electronic component in a plan view.

3. The electronic component module according to claim 1, further comprising an external connection terminal conductor disposed on the first main surface of the substrate, wherein the external connection terminal conductor is exposed from the first insulating resin and spaced apart from the first shield film.

4. The electronic component module according to claim 1, wherein the first shield film is provided in the first depression provided in the one surface of the first insulating resin.

5. The electronic component module according to claim 1, further comprising a plurality of external connection terminal conductors disposed on the first main surface of the substrate, wherein, in a plan view of the substrate, the first shield film is provided inside the plurality of external connection terminal conductors.

6. The electronic component module according to claim 1, further comprising:
another electronic component mounted on the second main surface of the substrate;
a second insulating resin covering a side of the second main surface; and
a second shield film covering an outer surface of the second insulating resin, a side surface of the substrate, and a side surface of the first insulating resin.

7. The electronic component module according to claim 6, wherein:
the other electronic component mounted on the second main surface includes a third electronic component and a fourth electronic component, the third electronic component and the fourth electronic component being spaced apart from each other;
a second conductive member is disposed between the third electronic component and the fourth electronic component on the second main surface of the substrate;
the second insulating resin includes a second depression exposing the second conductive member from the second insulating resin at a portion overlapping with the second conductive member; and
the second shield film is provided in the second depression of the second insulating resin and is connected to the second conductive member.

8. The electronic component module according to claim 6, wherein the second shield film and the first shield film are connected to each other.

9. The electronic component module according to claim 6, wherein the second shield film and the first shield film are separated from each other.
